(19) United States
(12) Patent Application Publication
(10) Pub. No.: US 2025/0330105 A1
(43) Pub. Date: Oct. 23, 2025

(54) TECHNOLOGIES FOR ENERGY GENERATING MULTILAYER COMPOSITE MATERIAL FOR PAD APPLICATION IN TRANSPORTATION SYSTEMS

(71) Applicant: THE TEXAS A&M UNIVERSITY SYSTEM, College Station, TX (US)

(72) Inventors: Shuza BINZAID, College Station, TX (US); Kazi Meharajul KABIR, College Station, TX (US)

(21) Appl. No.: 18/866,800

(22) PCT Filed: May 15, 2023
(86) PCT No.: PCT/US2023/066995

§ 371 Date: Nov. 18, 2024

Related U.S. Application Data
(60) Provisional application No. 63/343,734, filed on May 19, 2022.

(51) Int. Cl. H02N 2/18; E01C 9/00; H10N 30/00; H10N 30/30; H10N 30/88

(52) U.S. Cl. CPC H02N 2/18; E01C 9/00; H10N 30/30; H10N 30/704; H10N 30/88

(57) ABSTRACT

A multilayer composite energy generation device includes a bottom layer grouping including a fabric layer coated with a hydrophobic adhesive material, a middle layer including one or more piezoelectric transducers, and an upper layer include one or more fabric layers coated with a hydrophobic adhesive material. The middle layer may also be coated with a hydrophobic adhesive material. The piezoelectric transducer may include a thin-film piezoelectric material such as lead zirconium titanate (PZT). The hydrophobic adhesive material may be a paint-like polymeric material. The energy generation device may be coupled to a pavement segment such as a bicycle path, pedestrian path, or roadway.

### CROSS-REFERENCE TO RELATED APPLICATIONS

This application claims the benefit of and priority to U.S. Patent Application No. 63/343,734, entitled “ENERGY GENERATING MULTILAYER COMPOSITE MATERIALS PAD APPLICATION ON PAVEMENT FOR TRANSPORTS,” which was filed on May 19, 2022, which is incorporated by reference in its entirety.

### STATEMENT REGARDING FEDERALLY SPONSORED RESEARCH

This invention was made with Government support under Federal Grant No. 2025641, awarded by the National Science Foundation. The Government has certain rights in this invention.

### BACKGROUND

Conventional transportation systems may use fossil fuel energy sources or other energy sources that involve burning carbohydrate fuels. Global usage of such fossil fuel energy sources has created adverse environmental effects.

### SUMMARY

According to one aspect of the disclosure, a composite device, comprises a first layer comprising a first fabric layer coated with a hydrophobic adhesive material; a second layer coupled to the first layer, the second layer comprising a piezoelectric transducer; and a third layer coupled to the second layer, the third layer comprising a second fabric layer coated with a hydrophobic adhesive material. In an embodiment, the second layer comprises a thin-film piezoelectric film. In an embodiment, the thin-film piezoelectric film comprises lead zirconium titanate.

In an embodiment, the composite device further comprises a pair of DC power rails coupled to the piezoelectric transducer, wherein the DC power rails output voltage in response to impact on the composite device. In an embodiment, the second layer comprises a plurality of piezoelectric transducers arranged in an grid; and a plurality of charge collection modules, wherein each charge collection module is coupled to a piezoelectric transducer of the plurality of piezoelectric transducers, and wherein each charge collection module is coupled to the pair of DC power rails. In an embodiment, a DC power rail of the pair of DC power rails is coupled to a non-DC floating ground.

In an embodiment, the second layer is coated with a hydrophobic adhesive material. In an embodiment, the hydrophobic adhesive material of the second layer comprises a hardened polymer spray material.

In an embodiment, the first fabric layer comprises a cotton-polyester fabric. In an embodiment, the first layer comprises a plurality of hydrophobic adhesive materials coating the first fabric layer. In an embodiment, the hydrophobic adhesive materials of the first layer comprises a mixture of two hydrophobic adhesive materials.

In an embodiment, the third layer comprises a third fabric layer coated with the hydrophobic adhesive material. In an embodiment, the second fabric layer comprises a cotton-polyester fabric and the third fabric layer comprises a polyester microfleece. In an embodiment, the third layer comprises a plurality of hydrophobic adhesive materials coating the second fabric layer and the third fabric layer. In an embodiment, the hydrophobic adhesive materials of the third layer comprises a mixture of three hydrophobic adhesive materials.

In an embodiment, the hydrophobic adhesive material of the first layer and the third layer are flexible. In an embodiment, the hydrophobic adhesive material of the first layer and the third layer comprise a paint-like polymeric material.

According to another aspect, a transportation system comprises a pavement segment and an energy generating pad coupled to the pavement segment. The energy generating pad comprises a multilayer composite material including a hydrophobic adhesive material and a piezoelectric transducer. In an embodiment, the pavement segment comprises a bicycle path, a pedestrian path, or a roadway.

In an embodiment, the multilayer composite material comprises a first layer comprising a first fabric layer coated with a hydrophobic adhesive material; a second layer coupled to the first layer, the second layer comprising a piezoelectric transducer; and a third layer coupled to the second layer, the third layer comprising a second fabric layer coated with a hydrophobic adhesive material. The first layer of the energy generating pad is coupled to the pavement segment. In an embodiment, the second layer comprises a thin-film piezoelectric film. In an embodiment, the thin-film piezoelectric film comprises lead zirconium titanate.

In an embodiment, the transportation system further comprises a pair of DC power rails coupled to the piezoelectric transducer, wherein the DC power rails output voltage in response to impact on the composite device. In an embodiment, the second layer comprises a plurality of piezoelectric transducers arranged in an grid; and a plurality of charge collection modules, wherein each charge collection module is coupled to a piezoelectric transducer of the plurality of piezoelectric transducers, and wherein each charge collection module is coupled to the pair of DC power rails. In an embodiment, a DC power rail of the pair of DC power rails is coupled to a non-DC floating ground.

In an embodiment, the second layer is coated with a hydrophobic adhesive material. In an embodiment, the hydrophobic adhesive material of the second layer comprises a hardened polymer spray material.

In an embodiment, the first fabric layer comprises a cotton-polyester fabric. In an embodiment, the first layer comprises a plurality of hydrophobic adhesive materials coating the first fabric layer. In an embodiment, the hydrophobic adhesive materials of the first layer comprises a mixture of two hydrophobic adhesive materials.

In an embodiment, the third layer comprises a third fabric layer coated with the hydrophobic adhesive material. In an embodiment, the second fabric layer comprises a cotton-polyester fabric and the third fabric layer comprises a polyester microfleece. In an embodiment, the third layer comprises a plurality of hydrophobic adhesive materials coating the second fabric layer and the third fabric layer. In an embodiment, the hydrophobic adhesive materials of the third layer comprises a mixture of three hydrophobic adhesive materials.

In an embodiment, the hydrophobic adhesive material of the first layer and the third layer are flexible. In an embodiment, the hydrophobic adhesive material of the first layer and the third layer comprise a paint-like polymeric material.

### BRIEF DESCRIPTION OF THE DRAWINGS

The concepts described herein are illustrated by way of example and not by way of limitation in the accompanying figures. For simplicity and clarity of illustration, elements illustrated in the figures are not necessarily drawn to scale. Where considered appropriate, reference labels have been repeated among the figures to indicate corresponding or analogous elements.

FIG. 1 is a perspective view of a multilayer composite energy generation device;

FIG. 2 is an exploded view of the multilayer composite energy generation device of FIG. 1;

FIG. 3 is a detail view of an energy generation layer of the multilayer composite energy generation device of FIGS. 1-2;

FIG. 4 is a schematic diagram of a transportation system including a multilayer composite energy generation device of FIGS. 1-3; and

FIG. 5 is a chart illustrating experimental results that may be achieved with the multilayer composite energy generation device of FIGS. 1-4.

### DETAILED DESCRIPTION OF THE DRAWINGS

While the concepts of the present disclosure are susceptible to various modifications and alternative forms, specific embodiments thereof have been shown by way of example in the drawings and will be described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

References in the specification to “one embodiment,” “an embodiment,” “an illustrative embodiment,” etc., indicate that the embodiment described may include a particular feature, structure, or characteristic, but every embodiment may or may not necessarily include that particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described. Additionally, it should be appreciated that items included in a list in the form of “at least one A, B, and C” can mean (A); (B); (C); (A and B); (A and C); (B and C); or (A, B, and C). Similarly, items listed in the form of “at least one of A, B, or C” can mean (A); (B); (C); (A and B); (A and C); (B and C); or (A, B, and C).

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features.

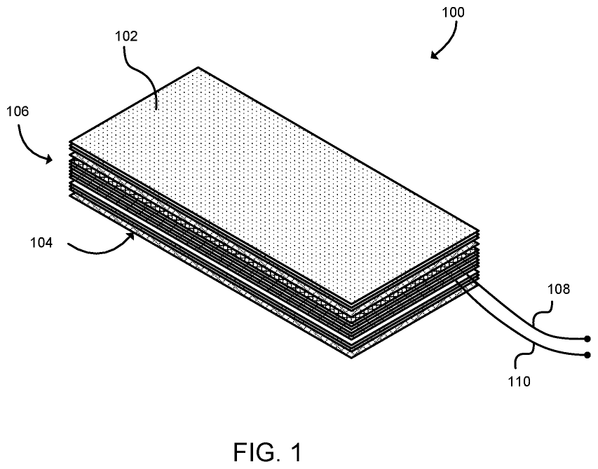

Referring now to FIGS. 1-3, an illustrative multilayer, composite energy generating device 100 includes a top surface 102, a bottom surface 104, and multiple layers 106. As described further below, the layers 106 include one or more energy generation layers that are coupled to power leads 108, 110. The bottom surface 104 of the composite device 100 may be attached to a bike path, pedestrian path, roadway, pavement, or other transportation surface. In use, as described further below, as vehicles and/or pedestrians travel over the composite device 100, the energy generation layer harvests energy from the impact of those vehicles and/or pedestrians and outputs electrical energy via the power leads 108, 110. Accordingly, the composite device 100 may provide a zero-emission alternative energy generation source for application on numerous pavement types. Further, the composite device 100 may be manufactured from common, low-cost materials and thus may be suitable for deployment anywhere in the world. As described further below, the composite device 100 is flexible, waterproof, and durable and thus may be appropriate for use with bicycles or with heavier vehicles.

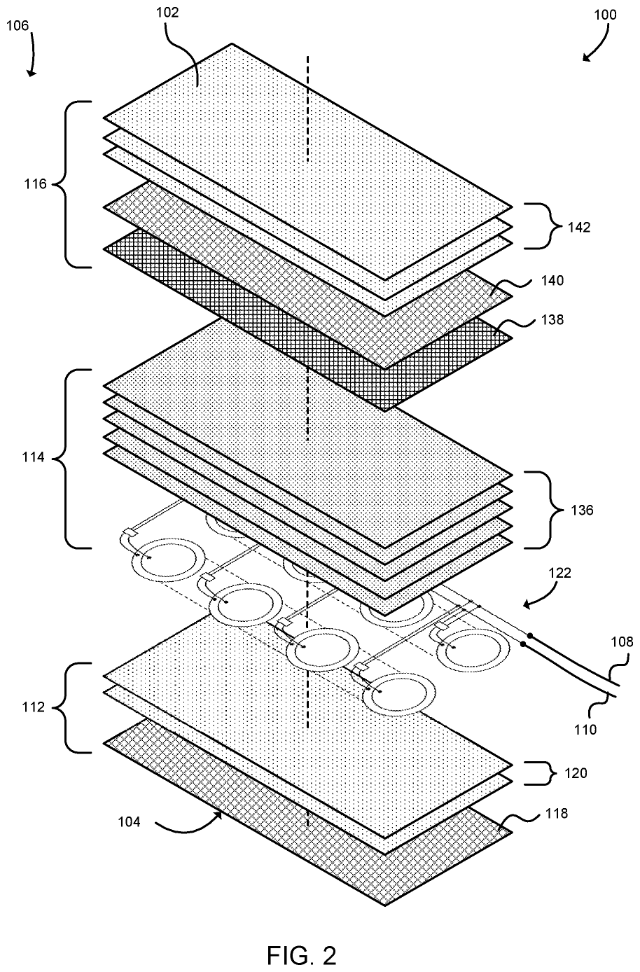

As shown in the exploded view of FIG. 2, the layers 106 may include a bottom layer group 112, a middle layer group 114, and a top layer group 116. The illustrative bottom layer group 112 includes a fabric layer 118 and two hydrophobic coating layers 120. The fabric layer 118 may be formed from a durable fabric such as a cotton/polyester blend fabric. Each of the hydrophobic coating layers 120 may be formed from a paint-like polymeric layer, such as an acrylic coating, an adhesive coating, or other adhesive fluid. The hydrophobic coating layers 120 may be applied to the fabric layer 118 as a liquid and allowed to dry, cure, or otherwise solidify. When solidified, the hydrophobic coating layers 120 on the fabric layer 118 form a flexible, waterproof layer that is suitable for attachment to a pavement surface. While flexible, the solidified hydrophobic coating layers 120 on the fabric layer 118 may exhibit bending strength, for example by bending with minimal unrecoverable stress marks. The solidified hydrophobic coating layers 120 on the fabric layer 118 may be tested for bending strength, flexibility, and waterproofness.

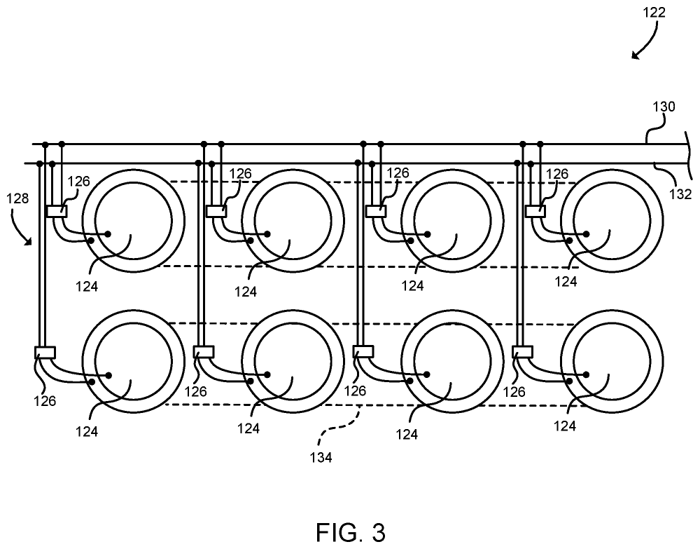

The middle layer group 114 includes an energy generation layer 122, as shown in the detail view of FIG. 3. As shown, the energy generation layer 122 includes multiple piezoelectric transducer pads 124 arranged in a grid. Although illustrated as being arranged in a grid, in other embodiments the piezoelectric transducer pads 124 may be arranged linearly or in any other appropriate arrangement. Each piezoelectric transducer pad 124 may include a thin-film piezoelectric material such as lead zirconium titanate (PZT). When each piezoelectric transducer pad 124 is subject to mechanical stress, such as when a vehicle or pedestrian compresses the energy generation layer 122, the piezoelectric material generates an electric charge.

As shown, each piezoelectric transducer pad 124 is connected to a corresponding charge collection module 126 via a wiring network 128. Each charge collection module 126 collects and/or converts electric charge generated by the piezoelectric transducer pad 124 into usable electrical voltage and/or current. For example, each charge collection embodiment may include one or more charge amplifier, charge pump, rectifier, voltage converter, and/or other electronic component configured to collect charge from the piezoelectric transducer pads 124.

Each of the charge collection modules 126 is connected via the wiring network 128 to a pair of direct current (DC) rails 130, 132. Those DC rails 130, 132 are connected to the power leads 108, 110, respectively, and thus may be used to supply power from the energy generation layer 122 to the power leads 108, 110. One or more external loads may be coupled to the power leads 108, 110. Further, although illustrated as including charge collection modules 126 coupled to the piezoelectric transducer pads 124, it should be understood that in some embodiments the piezoelectric transducer pads 124 may be coupled via the DC power rails 130, 132 directly to a non-DC floating ground.

In some embodiments, the energy generation layer 122 may include one or more support wires 134 coupled to the piezoelectric transducer pads 124. The support wires 134 may maintain the piezoelectric transducer pads 124 in the grid or other predetermined arrangement.

Referring again to the exploded view of FIG. 2, the middle layer 114 further includes five hydrophobic coating layers 136. Each of the hydrophobic coating layers 136 may be embodied as a spray-on polymer coating. The hydrophobic coating layers 136 may be rubberized or include additional rubberization as compared to the hydrophobic coating layers 120. Accordingly, the middle layer 114 may be more compliant as compared to the bottom layer 112 or, as described further below, the top layer 116. Additionally or alternatively, in some embodiments the hydrophobic coating layers 136 may be embodied as paint-like fluid layers similar to the hydrophobic coating layers 120.

The illustrative top layer group 116 includes a fabric layer 138, a fabric layer 140, and three hydrophobic coating layers 142. The fabric layer 138 may be formed from a felt-like fabric, such as a polyester microfiber. The fabric layer 140 may be formed from a durable fabric such as a cotton/polyester blend fabric, similar to the fabric layer 118. Each of the hydrophobic coating layers 142 may be formed from a paint-like polymeric layer similar to the hydrophobic coating layers 120, such as an acrylic coating, an adhesive coating, or other adhesive fluid. The hydrophobic coating layers 142 may be applied to the fabric layers 138, 140 as a liquid and allowed to dry, cure, or otherwise solidify. When solidified, the hydrophobic coating layers 142 on the fabric layers 138, 140 form a flexible, waterproof layer that is suitable for use as a transportation surface. While flexible, the solidified hydrophobic coating layers 142 on the fabric layers 138, 140 may exhibit bending strength, for example by bending with minimal unrecoverable stress marks. The solidified hydrophobic coating layers 142 on the fabric layers 138, 140 may be tested for bending strength, flexibility, and waterproofness.

Although illustrated in FIGS. 1-3 as including a particular number and/or arrangement of fabric layers 118, 138, 140 and hydrophobic coating layers 120, 136, 142, it should be understood that in different embodiments, the composite device 100 may include a different number and/or arrangement of layers. For example, the size of the energy generation layer 122 may be changed to increase energy generation. As another example, the number and/or thickness of the fabric and/or hydrophobic coating layers may be changed to adjust the weight tolerance level of the composite device 100. Similarly, fewer fabric layers and/or hydrophobic coating layers may be used to reduce cost of the composite device 100.

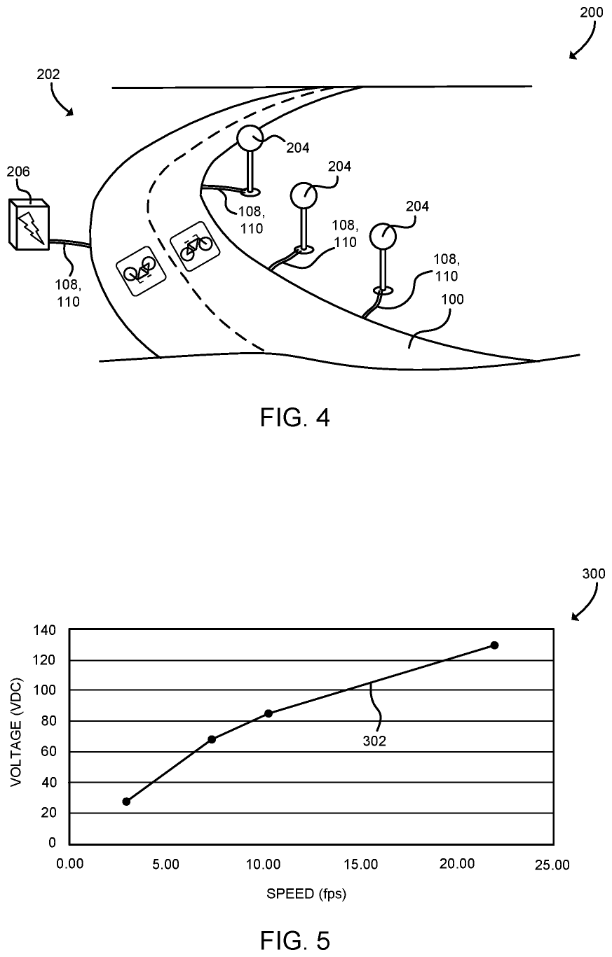

Referring now to FIG. 4, diagram 200 shows an illustrative transportation system that includes a multilayer composite energy generation pad device 100. The transportation system includes a bicycle path 202, which is illustratively a pavement path configured for use by bicycles, pedestrians, and/or other vehicles of similar size and/or weight. The composite device 100 is attached to the bicycle path 202. For example, the composite device 100 may be bonded or otherwise attached to a pavement surface of the bicycle path 202. As bicycles travel over the bicycle path 202, the weight of the bicycle compresses the composite device 100, which generates electrical energy. Multiple devices or other energy loads may be connected to the composite device 100 in order to use this generated energy. For example, as shown, multiple streetlights 204 or other lighting systems may be connected to the composite device 100 via the power leads 108, 110. As another example, a public charging station 206 or other charging infrastructure may be connected to the composite device 100 via the power leads 108, 110. Of course, in other embodiments, other loads such as energy storage devices, microgrids, or other loads may be connected to the composite device 100. Similarly, although illustrated as being coupled to a bicycle path 202, in other embodiments the composite device 100 may be coupled to a pedestrian walkway, a road, a pavement segment, or any other appropriate transportation infrastructure.

Referring now to FIG. 5, chart 300 illustrates experimental results that may be a achieved by an embodiment of the multilayer composite energy generation pad device 100. In an experiment, a composite device 100 was constructed that was about 3 feet (1 m) in length. The composite device included thin-film PZT cells in the energy generation layer 122. The composite device 100 was placed on a hard surface, and the power leads 108, 110 were connected to electrical measurement equipment (e.g., a digital multimeter or similar device). A bicycle with rider having a combined weight of about 142 pounds was ridden over the composite device 100 at multiple speeds. Curve 302 illustrates measured voltage versus bicycle speed. As shown, measured voltage for riding speeds ranged from about 68 V DC to 130 V DC, and voltage increased with increasing speed. IN this experiment, energy was harvested from the composite device 100 at a rate of about 661.53 mW per piezoelectric cell from the illustrative 3-foot segment of composite device 100. The device 100 continued to perform successfully over repeated tests.

In another experiment, a multilayer composite energy generation pad device 100 was constructed including relatively thicker fabric and/or hydrophobic coating layers as compared to the previous experiment. This experimental device 100 also included thin-film PZT cells in the energy generation layer 122. The experimental device 100 was tested with heaver compressive weight. This experimental device 100 successfully tolerated weight over 1,000 pounds. Accordingly, the device 100 may scale to transportation systems with vehicles heavier than bicycles, for example to be used with a roadway carrying automobile traffic.

1. A composite device, comprising:
a first layer comprising a first fabric layer coated with a hydrophobic adhesive material;
a second layer coupled to the first layer, the second layer comprising a piezoelectric transducer; and
a third layer coupled to the second layer, the third layer comprising a second fabric layer coated with a hydrophobic adhesive material.

2. The composite device of claim 1, wherein the second layer comprises a thin-film piezoelectric film.

3. The composite device of claim 2, wherein the thin-film piezoelectric film comprises lead zirconium titanate.

4. The composite device of claim 1, further comprising a pair of DC power rails coupled to the piezoelectric transducer, wherein the DC power rails output voltage in response to impact on the composite device.

5. The composite device of claim 4, wherein the second layer comprises:
a plurality of piezoelectric transducers arranged in an grid; and
a plurality of charge collection modules, wherein each charge collection module is coupled to a piezoelectric transducer of the plurality of piezoelectric transducers, and wherein each charge collection module is coupled to the pair of DC power rails.

6. The composite device of claim 4, wherein a DC power rail of the pair of DC power rails is coupled to a non-DC floating ground.

7. The composite device of claim 1, wherein the second layer is coated with a hydrophobic adhesive material.

8. The composite device of claim 7, wherein the hydrophobic adhesive material of the second layer comprises a hardened polymer spray material.

9. The composite device of claim 1, wherein the first fabric layer comprises a cotton-polyester fabric.

10. The composite device of claim 1, wherein the first layer comprises a plurality of hydrophobic adhesive materials coating the first fabric layer.

11. The composite device of claim 10, wherein the hydrophobic adhesive materials of the first layer comprises a mixture of two hydrophobic adhesive materials.

12. The composite device of claim 1, wherein the third layer comprises a third fabric layer coated with the hydrophobic adhesive material.

13. The composite device of claim 12, wherein the second fabric layer comprises a cotton-polyester fabric and the third fabric layer comprises a polyester microfleece.

14. The composite device of claim 12, wherein the third layer comprises a plurality of hydrophobic adhesive materials coating the second fabric layer and the third fabric layer.

15. The composite device of claim 14, wherein the hydrophobic adhesive materials of the third layer comprises a mixture of three hydrophobic adhesive materials.

16. The composite device of claim 1, wherein the hydrophobic adhesive material of the first layer and the third layer are flexible.

17. The composite device of claim 1, wherein the hydrophobic adhesive material of the first layer and the third layer comprise a paint-like polymeric material.

18. A transportation system comprising:
a pavement segment; and
an energy generating pad coupled to the pavement segment, wherein the energy generating pad comprises a multilayer composite material including a hydrophobic adhesive material and a piezoelectric transducer.

19. The transportation system of claim 18, wherein the pavement segment comprises a bicycle path, a pedestrian path, or a roadway.

20. The transportation system of claim 18, wherein the multilayer composite material comprises:
a first layer comprising a first fabric layer coated with a hydrophobic adhesive material;
a second layer coupled to the first layer, the second layer comprising a piezoelectric transducer; and
a third layer coupled to the second layer, the third layer comprising a second fabric layer coated with a hydrophobic adhesive material;
wherein the first layer of the energy generating pad is coupled to the pavement segment.

21.-36. (canceled)
